(19) United States
(12) Patent Application Publication
(10) Pub. No.: US 2024/0125451 A1
(43) Pub. Date: Apr. 18, 2024

(54) LIGHT SOURCE FOR THE SIGNALLING SYSTEM OF A MOTOR VEHICLE

(71) Applicant: VALEO VISION, BOBIGNY Cedex (FR)

(72) Inventors: Antoine DE LAMBERTERIE, BOBIGNY Cedex (FR); Alexandre VAL, BOBIGNY Cedex (FR)

(73) Assignee: VALEO VISION, BOBIGNY Cedex (FR)

(21) Appl. No.: 18/264,438

(22) PCT Filed: Feb. 9, 2022
(86) PCT No.: PCT/EP2022/053181

§ 371 Date: Aug. 7, 2023

(30) Foreign Application Priority Data
Feb. 9, 2021 (FR) FR2101238

(51) Int. Cl. F21S 43/20; F21S 43/16; F21S 43/30

(52) U.S. Cl. CPC F21S 43/26; F21S 43/16; F21S 43/30

(57) ABSTRACT

A light source of a matrix arrangement of light sources of a motor vehicle lighting module includes a substrate having an upper face, a lower face opposite the upper face, and an electronic circuit. At least one light-emitting element is mounted on the upper face of the substrate and includes a light-emitting part. Also included is an optical device for forming the light beams emitted by the light-emitting element, and the lower face includes connection contacts connected to the electronic circuit, the electronic circuit being adapted to power the at least one light-emitting element. The light-emitting part of at least one light-emitting element having a surface area of less than 40,000 μm². The optical device includes an optical element that is produced by being molded onto the at least one light-emitting element and at least partially onto the upper face of the substrate.

The invention relates to the field of lighting and/or light signalling for motor vehicles. More specifically, the invention relates to the field of screens integrated in motor vehicle lighting or light-signalling lighting modules.

It is known practice to integrate screens in motor vehicle lighting modules, for example in tail lights. These screens are for example produced by means of arrays of a large number of light sources that can be selectively activated, the dimensions of which are small enough for it to be possible to display information, for example in the form of messages or pictograms, on these screens with a satisfactory resolution. Such information thus makes it possible to improve the signalling given by the motor vehicle, for example by contextualizing a given signalling function with a message or giving it an accompanying message. For safety reasons, it is however necessary that the information displayed there are visible in a wide field of view.

However, light sources with small dimensions are limited in terms of flux and it is difficult to form, from an array arrangement of these light sources and for a reasonable cost, a module which is able to form a signalling device capable of allowing good visibility of the message during the day and/or to perform a regulatory function, notably a rear position light function, and/or a BRAKE function and/or a turn indicator function having a light distribution corresponding at least to the minimum lighting at angles of observation as defined in the UNDECA regulations no. 6-Rev. 7 and no. 7-Rev. 7 in force on the filing date.

For signalling lights having a limited number of light sources, optical units for meeting the regulatory requirements are known. However, these solutions are complex to implement over a significant number of light sources, for example several hundred or several thousand, for each light module: it is difficult to imagine the mass production of such light sources.

Another technical problem of light sources with small dimensions is the light output. This is because the specified regulatory functions require a high flux and it is then necessary to use arrangements of light sources having high electrical power densities per unit area to reach the light intensities required. The problem with these arrangements of light sources which have a high electrical power density is the heat emitted being converted into thermal power per unit area, which it is then difficult to dissipate, in particular into the surroundings of motor vehicles; in addition, this power density leads to a high consumption of electricity.

In order to overcome these problems, what is proposed is a light source for an array arrangement of light sources for a motor vehicle lighting module, the light source having:
a substrate having an upper face, a lower face opposite to the upper face, and an electronic circuit,
at least one electroluminescent element which is mounted on the upper face of the substrate and has a light-emitting part,
an optical unit for shaping the rays emitted by said electroluminescent element,
said lower face having connection contacts connected to the electronic circuit, the electronic circuit being designed to supply power to the at least one electroluminescent element,
the light-emitting part of at least one electroluminescent element having a surface area less than 40 000 μm²,
said optical unit comprising an optical element made by molding onto at least one electroluminescent element and at least partially onto the upper face of the substrate.

An array arrangement of light sources is understood to mean an arrangement of light sources in a lattice layout, that is to say an arrangement of multiple light sources which is repeated at least once, preferably at least three times. For example, the lattice may be made up of light sources disposed at the corners of a parallelogram. Preferably, the light sources of the array arrangement are identical, but it is possible to have a restricted number of types of light sources, for example less than 5, for example 2.

An optical unit for shaping the light rays is understood to mean an optical system having at least one optical element which deflects the light rays coming from at least one electroluminescent element so as to shape them.

An electronic circuit is understood to mean any arrangement of tracks having or not having electronic components for supplying power to the electroluminescent element.

Shaping is understood to mean either facilitating the extraction of the light rays or concentrating the light rays. In the present case of an optical unit deposited directly on an electroluminescent element, “facilitating the extraction of the light rays” is understood to mean letting through the luminous flux that would be blocked by internal reflection in the absence of a dedicated optical unit for shaping the light rays. “Concentrating the light rays” is understood to mean modifying the distribution of a beam from the electroluminescent element so as to increase an intensity along a main direction and/or reduce the intensity in directions away from the main direction.

The optical unit for shaping the light rays coming from at least one electroluminescent element is obtained by molding an optical unit onto the at least one electroluminescent element and at least partially onto the upper face of the substrate, preferably by a process comprising a single step of applying a material that is to be molded. This is understood to mean that the optical unit for shaping the light rays has a part which is in contact with the upper face of the substrate and a part which is in contact with the electroluminescent element. Preferably, the material that is to be molded is molded by applying a molding die. Preferably, the material that is to be molded is a resin which is curable, preferably curable by irradiation, preferably curable by UV irradiation. When the material that is to be molded is curable by irradiation, the molding dies are preferably at least partially translucent to the irradiation making it possible to cure the molding material. Alternatively, the material that is to be molded is curable by a thermal process.

In a particular example, the molding process involves multiple molding dies for producing optical units for shaping the light rays with different geometries in a single molding step.

The optical unit for shaping the light rays may be molded individually onto each light source. Alternatively, the optical unit for shaping the light rays may be molded onto a plurality of light sources according to the invention; in this case, multiple dies may be used to mold the optical unit for shaping the light rays, such that the molding is carried out in a single step for an array arrangement of light sources according to the invention.

The upper face of the substrate is planar or may be similar to a plane at least locally.

The optical unit for shaping the light rays coming from the light source may comprise a transparent optical element and/or a reflector.

Emitting part of the electroluminescent element is generally understood to mean that part of an electroluminescent element that emits most, for example at least 80%, preferably at least 90%, of the group of light rays emitted by at least one electroluminescent element. The surface area of this emitting part is typically evaluated as that surface area of the electroluminescent element mounted on the substrate that is visible from an axis normal to the outer face of the substrate before the optical unit for shaping the light rays is molded.

The at least one electroluminescent element is mounted on the substrate, that is to say that it may for example be deposited on the electrical contacts of the upper face of the substrate. In another example, the at least one electroluminescent element is embedded in the substrate and only its light-emitting surface emerges from the substrate. In another example, the at least one electroluminescent element is embedded in the substrate and its light-emitting surface continues the upper face of the substrate.

The presence of connection contacts on the lower face makes it possible to easily mount the light source on a support which itself is provided with connection contacts, making it possible to form an array arrangement of light sources. For example, the connection contacts of the support and/or of the light source may comprise a deposition of an alloy (for example SnAg, AuSn, AuIn) which is able to create a conductive metallic bond with the opposite contacts, notably by way of a thermal process.

The connection contacts are connected to the electronic circuit and the electronic circuit is designed to supply power to at least one electroluminescent element, this making it possible to supply power to the light source entirely through the contacts of the support. For example, the electronic circuit is made up of vias connecting tracks for supplying power to the electroluminescent element. In this way, it is possible to mount the light source on the support with very few operations, preferably comprising a single operation requiring the light source to be handled. As a result, it is possible to effectively mount a large number of light sources, for example several hundreds, several thousands, several tens or hundreds of thousands, or even several millions of light sources. Depending on the number of light sources to be mounted on the support, it is possible to use an automated mounting process of the pick-and-place type or mass transfer type for the positioning of the light sources on the support.

The manufacture of an optical unit by direct molding onto the substrate makes it possible to mass produce optical units for shaping the light rays, notably by a collective manufacturing process, notably on a wafer, which is preferably collective until a singulation of light sources according to the invention. The collectivization of the production steps then enables both a significant reduction in the manufacturing costs and time and the production of millions of sources, this making it possible to use such sources in motor vehicle signalling modules.

In one example, the electronic circuit consists of a simple interconnection network for connecting the at least one electroluminescent element to the contacts of the support.

The optical unit for shaping the light rays coming from the at least one electroluminescent element allows one and the same electroluminescent element to contribute more effectively to a distribution which is compatible with the aforementioned regulations. The effectiveness of this contribution is significant because it makes it possible to make a greater contribution to a given function for the same number of light sources. It will therefore be understood that the invention makes it possible to improve the cost of a lighting function performed by an array arrangement of light sources. In one exemplary embodiment, an array arrangement of light sources according to the invention makes it possible to fully achieve the rear position light and brake light or indicator functions.

Since the optical unit for shaping the light rays is produced in direct contact with the at least one electroluminescent element, losses of light by reflection on an input surface of the optical unit for shaping the light rays are avoided.

Since the optical unit for shaping the light rays also extends on the upper face of the substrate, it makes it possible to extend a perceived surface area of the light source according to the invention.

The invention thus enables better use of the luminous flux from each source and reduces the necessary power density, and thus the thermal power per unit area, all the more to attain a given light intensity contribution for an array arrangement of light sources according to the invention, such that a signalling device that has said array arrangement and is intended to perform a signalling function according to the aforementioned regulations can supply the light intensity required by said regulations. The consumption of energy and dissipation of heat of an array arrangement according to the invention are thus reduced over the prior art.

Advantageously, the substrate supports a restricted number of electroluminescent elements on its upper face. Preferably, such a substrate of light sources is obtained from an initial substrate on which are mounted the electroluminescent elements, which is then cut into a multitude of substrates of light sources.

Advantageously, the optical unit for shaping the light rays has a Fresnel lens. When the optical unit for shaping the light rays has such a lens, an amount of material for the production of the optical unit for shaping the light rays is reduced, and a size of the light sources is reduced.

Advantageously, the at least one electroluminescent element is a light-emitting diode or LED.

Advantageously, the at least one electroluminescent element emits a red light, in particular a red light designed to perform a signalling function, in particular a red which meets the regulatory conditions of chromaticity that are defined in the UNECE regulation no. 7-Rev. 7 in force on the filing date of the application.

Advantageously, the light source comprises an electroluminescent element emitting an amber light, in particular a light designed to perform a signalling function, in particular an amber light which meets the regulatory conditions of chromaticity for turn indicators that are defined in the UNECE regulation no. 6-Rev. 7 in force on the filing date of the application. In one example, the light source comprises one or more electroluminescent elements that emit said amber light to the exclusion of other colors.

Advantageously, the light source comprises an electroluminescent element that emits a turquoise or magenta light which is able to perform signalling on a motor vehicle which has an autonomous driving mode.

Advantageously, the emitting part of the at least one electroluminescent element has a surface area less than 40 000 μm², advantageously the surface area of the emitting part has dimensions less than 200 μm×200 μm. When at least one electroluminescent element is an LED, it is then referred to as an electroluminescent element of mini-LED type.

Preferably, the emitting part of the at least one electroluminescent element has a surface area less than 2 500 μm², advantageously the surface area of the emitting part has dimensions less than 50 μm×50 μm. When the at least one electroluminescent element is an LED, it is then referred to as an electroluminescent element of micro-LED type.

Advantageously, the at least one electroluminescent element is a singulated LED which does not have other LEDS epitaxially grown on one and the same base. In this way, the electroluminescent elements can be individually validated, preferably before being mounted on the substrate, so as to avoid producing light sources having non-functional elements. As a result, the efficiency of the manufacture of the light source is improved and the cost is reduced.

Advantageously, the spacing between the centers of two adjacent light sources in the array arrangement of light sources is less than 1 mm, preferably less than 500 μm, preferably between 200 μm and 400 μm, preferably between 250 μm and 350 μm. The gaps between the light sources may advantageously be small, for example less than 100 μm, preferably 50 μm, such that the spacing between the electroluminescent elements of the light sources is even. In a preferred embodiment, the light sources have a single electroluminescent element located in the center of the light source, and the centers of the light sources are spaced apart by a spacing interval, and the spacing between the sides of the light sources is greater than one quarter of said spacing interval, preferably than one third of this interval. Such an arrangement makes it possible to avoid manufacturing problems and to take account of assembly and installation margins of other elements on the support for light sources.

Advantageously, the surface area of the emitting part of at least one electroluminescent element is at least two times, preferably at least three times, preferably at least five times, preferably at least ten times less than the surface area of the upper face of the substrate. A larger surface area of the upper face of the substrate makes it possible to receive a larger optical unit for shaping the light rays, but also to increase the size of the connection contacts such that a cost-effective substrate can be used.

Advantageously, the surface area of the emitting part of the at least one electroluminescent element is at least two times, preferably at least three times, preferably at least five times, preferably at least ten times less than the surface area of the output face of the optical unit for shaping the light rays as viewed from an axis normal to the substrate, and preferably ten times less than the surface area of the output face of the optical unit for shaping the light rays as seen from an axis normal to the substrate. In this way, a surface area of the electroluminescent element that is perceived through the optical unit for shaping the light rays is maximized, this enabling better perceived homogeneity of an array of light sources according to the invention and better visual comfort, and better use of the luminous flux coming from the electroluminescent element.

When the light source is mounted in a module on the vehicle, the shaping optical unit concentrates the rays emitted by the light source more vertically than horizontally. This can be measured by placing the source, or the lighting device containing it, on an intensity measuring bench provided with a goniometer, in the same orientation as when it is mounted on the motor vehicle.

A reference attitude plane of maximum intensity and a reference vertical plane of maximum intensity are defined. Said reference attitude plane is a plane comprising the direction of maximum intensity of the light source and a transverse axis of the vehicle. The reference vertical plane is a vertical plane comprising the direction of maximum intensity.

A front-rear axis of the motor vehicle is understood to mean a horizontal axis of the motor vehicle which is oriented in a preferred direction of forward travel of the motor vehicle.

A transverse axis of the motor vehicle is understood to mean a horizontal axis of the motor vehicle which is oriented perpendicularly in relation to a front-rear axis of the motor vehicle.

When the light intensity of the lit light source is measured in the reference attitude plane, the intensity value measured at a given angle around the vertical plane is greater than the value measured when the light intensity of the lit light source is measured in the reference vertical plane at an angle around the horizontal plane corresponding to said given angle.

The reference attitude plane forms an angle with a horizontal plane of the motor vehicle of less than 10°, preferably less than 5°, preferably less than 2°. Preferably, said reference attitude plane is horizontal.

Preferably, when the intensity is measured in the reference vertical plane, it is greater than a first predetermined value in the directions above the horizontal that form an angle greater than a first given angle with the horizontal plane of the vehicle, and less than the first predetermined value in the directions above the horizontal that form an angle less than the first given angle with the horizontal plane of the vehicle, with the first given angle being between 10° and 45°, and the first predetermined value being between 20% and 50% of the maximum intensity.

Preferably, when the intensity is measured in the reference vertical plane, it is greater than a second predetermined value in the directions below the horizontal that form an angle less than a second given angle with the horizontal plane of the vehicle, and less than the second predetermined value in the directions below the horizontal that form an angle greater than the second predetermined value with the horizontal plane of the vehicle, with the second given angle being between 5° and 30°, and the second predetermined value being between 10% and 40% of the maximum intensity. An outside observer who is close enough to the motor vehicle when it is in operation, for example a pedestrian, typically has a viewpoint in a plane which is higher than a signalling device of the motor vehicle, typically above the upper envelope plane. As a result, when the signalling device of the motor vehicle has a lighting module comprising an array of light sources according to the invention, the intensity perceived by the pedestrian is limited and they are not dazzled by the signalling device. The pedestrian can therefore comfortably perceive a pattern or a message displayed by the lighting module. An esthetic and/or communication function accompanied by the pattern is therefore facilitated.

In a preferred embodiment, the intensity of the light emitted by the light source is less than a predetermined fraction of the maximum intensity of the light coming from the light source in the directions of the reference vertical plane that form an angle of 45° upwardly with a horizontal plane which is greater than this value below, said third predetermined value being between 20% and 50% of the maximum intensity, preferably between 30% and 40%. Although this value clearly exceeds the minimums imposed by the aforementioned regulations, it makes it possible to use the array arrangement of light sources to perform a display function for a pedestrian who is close to the motor vehicle, for example located less than 2 m from the motor vehicle, in intense outside lighting conditions. In this way, an esthetic function of the module is reinforced for a pedestrian who is close to the motor vehicle. In addition, the display of a message is thus easily perceptible in conditions in which there is reflection from the outer lens of the lighting device.

It will be understood that higher intensities, for example when the third predetermined value is comprised between 30% and 40% of the maximum intensity, make it possible to obtain this effect while still retaining a certain effectiveness, and taking account of cases or manufacturing processes for the optical units for shaping the light rays that do not make it possible to ensure significant precision. The wider range of distribution of the intensities then makes it possible to ensure margins which correspond to tolerances in the precision of the optical units. In this way, less precise optical units still make it possible to obtain the minimums defined by the aforementioned regulations while still displaying a message which is luminous enough for a pedestrian who is close to the motor vehicle. A light source provided with such an optical unit for shaping the light rays is very effective at performing a motor vehicle signalling function as defined in the aforementioned regulations, notably much more so than a conventional light source which does not have an optical unit for shaping the light rays.

Preferably, in the same embodiment, the second given angle is between 5° and 20°, preferably between 10° and 15°, and the second predetermined value is between 10% and 20%. In this way, providing a high intensity toward the ground is avoided, this intensity not contributing to a signalling function as defined in the aforementioned regulations or to a lighting function, since pedestrians have a viewpoint located above the lighting device.

Alternatively, the optical unit for shaping the light rays coming from the at least one electroluminescent element forms a diopter similar to a spherical dome of which the center is located on at least one electroluminescent element, that is to say that it is similar to such a diopter allowing for the manufacturing tolerances. Such an optical unit for shaping the light rays makes it possible to optimally extract the light rays coming from said electroluminescent element.

Advantageously, the optical unit for shaping the light rays is a convergent optical unit of which at least one output surface for the light rays has an ellipsoidal or oval, preferably non-circular, cross section, with a cross section of the output surface here being defined by the intersection of the surface with a plane which contains a front-rear axis of the motor vehicle.

Advantageously, the output surface of the optical unit for shaping the light rays has a variable radius of curvature, which is advantageously variable and continuous on the output surface. In this case, the radius of curvature is advantageously larger on the edges of said optical unit and smaller in a central zone of the output surface, advantageously directed along a front-rear axis of the vehicle.

Advantageously, the optical unit for shaping the light rays concentrates the light rays more around a horizontal plane of the vehicle than around a vertical plane comprising a front-rear axis of the motor vehicle. This can be measured by placing the source, or the lighting device containing it, on an intensity measuring bench provided with a goniometer.

Advantageously, the shaping optical unit is rotationally asymmetrical in relation to any normal to the upper face of the substrate and/or asymmetrical in relation to any vertical plane of the vehicle and/or asymmetrical in relation to any horizontal plane of the vehicle. It will be understood that an asymmetry of the shaping optical unit is strictly equivalent to asymmetrical characteristics of concentration of the light rays.

In the case of rotational asymmetry, the characteristics of concentration of the optical unit for shaping the light rays are not invariant in rotation about any axis normal to the light-emitting surface of at least one electroluminescent element or to the upper face of the substrate. For example, this may be optical units having characteristics of concentration that are different around a vertical plane and around a horizontal plane. It is for example particularly advantageous that the optical unit for shaping the light rays concentrates the rays coming from at least one electroluminescent element more around a horizontal plane of the vehicle than around a vertical axis comprising the front-rear axis of the vehicle. In this way, a regulatory rear position light which can be seen effectively from most positions around the vehicle is easily obtained.

In the example of an optical unit for shaping the light rays which is asymmetrical in relation to any horizontal plane, it is possible to obtain a distribution concentrated around a horizontal plane of the motor vehicle, even in the event of the support for the array arrangement of light sources being inclined along a horizontal axis in relation to a plane normal to a front-rear axis of the motor vehicle. When the support for the array arrangement is thus inclined, an arrangement of light sources according to the invention, having optical units for shaping light rays that are asymmetrical in relation to any horizontal plane, makes it possible in particular to contribute effectively to a distribution which is compatible with the aforementioned regulations. In a particular example, such an arrangement makes it possible to fully achieve the rear position light and brake light functions while the support for the array arrangement is inclined in relation to a vertical plane normal to a front-rear axis of the vehicle.

In the example of an optical unit for shaping the light rays which is asymmetrical in relation to any vertical plane, it is possible to obtain a distribution concentrated around a horizontal plane of the motor vehicle, even in the event of the support for the array arrangement of light sources being inclined along a vertical axis in relation to a plane normal to a front-rear axis of the motor vehicle. When the support for the array arrangement is thus inclined, an arrangement of light sources according to the invention, having optical units for shaping light rays that are asymmetrical in relation to a vertical plane, makes it possible in particular to contribute effectively to a distribution which is compatible with the aforementioned regulations. In a particular example, such an arrangement makes it possible to fully achieve the rear position light and brake light functions while the support for the array arrangement is inclined in relation to a vertical plane comprising a front-rear axis of the vehicle.

In this way, when the optical unit for shaping the light rays exhibits rotational asymmetry in relation to any normal to the upper face of the substrate and/or in relation to any vertical plane of the vehicle and/or in relation to any horizontal plane of the vehicle, and when the rays coming from the at least one electroluminescent element are concentrated around a horizontal plane, it is possible to adapt the light source such that an array arrangement of light sources makes it possible to perform or contribute effectively to a signalling function of a motor vehicle, in particular a rear position light, even if the support for light sources is not perpendicular to a front-rear axis of the motor vehicle.

Advantageously, in the example of an asymmetrical optical unit for shaping the light rays and when the angle of inclination of the support for the array arrangement of light sources in relation to a plane is less than 20°, the optical unit for shaping the light rays is of the refractive and non-reflective type, this making it possible to obtain the regulatory distribution for lower production costs. Advantageously, when the angle of inclination of the support for the array arrangement of light sources in relation to a plane is greater than 20°, the optical unit for shaping the light rays has a refractive part and a reflective part, this making it possible to obtain the regulatory distribution for lower production costs.

In a particular example, the shaping optical unit concentrates the rays around a horizontal plane of the vehicle, and disperses the rays around a vertical plane of the vehicle. In this way, the visibility of an array arrangement of light sources is preserved for observers as long as they are in visual contact with the array arrangement.

Advantageously, the shaping optical unit has reflectors. Advantageously, the reflectors are designed to concentrate the light rays coming from at least one electroluminescent element. Such reflectors make it possible to concentrate the light rays coming from at least one electroluminescent element that have a trajectory close to that of the plane of the upper face of the substrate, for example rays emitted in a plane forming an angle with the plane of the upper face of the substrate of less than 30°, preferably less than 20°. In this way, the shaping optical unit avoids losses of light in directions in which it is unlikely that it will be perceived by an outside user; in addition, parasitic reflections are avoided.

Advantageously, the reflectors have an inclined face designed to concentrate rays coming from an electroluminescent element. Such a face may for example have a straight, parabolic or elliptical cross section. Advantageously, the reflectors are prisms of triangular cross section.

Advantageously, the reflectors are located on the substrate. Preferably, the reflectors are located on the substrate itself. Advantageously, the reflectors are manufactured by a process comprising a step of shaping a reflector body, for example by a semi-additive process or by molding, and preferably a step of depositing a reflective layer. In this way, the transparent part of the optical unit for shaping the light rays coming from the at least one electroluminescent element can be made by molding directly above the reflector. Alternatively, the reflectors are manufactured separately in the form of a part to be assembled on the substrate, preferably by adhesive bonding; for example, a grid or a panel with identical dimensions, made of an organic or inorganic material. Preferably, a reflective layer has been deposited at least partially on the part to be assembled. Preferably, the reflective layer comprises a metal layer, for example a deposition of copper, aluminum or gold.

In this way, the transparent part of the optical unit for shaping the light rays coming from the at least one electroluminescent element can be made by molding directly above the reflector. In one exemplary embodiment, the rays deflected by the reflectors are not deflected by the transparent part of the optical unit for shaping the light rays.

Advantageously, an antireflection coating and/or an organic coating and/or an inorganic coating is applied to the optical unit for shaping the light rays and/or to the sides of the light source. An antireflection coating makes it possible to reduce losses of light and light interference. An inorganic coating has the technical effect of reducing the permeability of the light source to elements in the surroundings of the motor vehicle, such as water and halogenated compounds, notably sulfur and chlorine compounds. Again advantageously, the antireflection coating is inorganic and it is deposited over the entire outer surface of the light source, except at least the connection contacts; in this way, the technical advantages are cumulated for one and the same operation. For example, the coating may be applied by a process of the PVD (physical vapor deposition) type or, in another example, by an atmospheric plasma deposition process.

Advantageously, the coating may comprise an optical element of the optical unit for shaping the light rays, for example a lens element or an adhesive directly and hermetically disposed on the emitting face of the electroluminescent element. However, it will be understood that any coating applied to an electroluminescent element is not to be interpreted as an optical element forming part of an optical unit for shaping the light rays.

Advantageously, the light source has a footprint and/or connection contacts which are asymmetrical along any plane normal to the plane of the upper face of the substrate. Footprint of the light source is understood to mean a surface area taken up on a mounting support by the light source and in which components, in particular other light sources, cannot be mounted. Preferably, the shape of the substrate, or the shape of its upper face or the shape of its lower face, defines the footprint of the light source. In this way, the footprint and/or the connection contacts of the source form a poka-yoke for avoiding incorrect assembly of the light source on the support, and for facilitating its positioning. This is particularly advantageous when the optical unit for shaping the light rays is itself asymmetrical. Alternatively, the optical unit for shaping the light rays has an asymmetrical footprint and the substrate has a square footprint, such that the spacing between the substrates is even and makes it possible to obtain a homogeneous appearance of the array arrangement of light sources on the support, in particular as regards the spacing lines between the substrates of the light sources.

Advantageously, the light source has a footprint with a short dimension in a first direction and a long dimension in a second direction. This makes it possible to ensure the correct orientation of the light source on the support for light sources during assembly. Furthermore, when the light source is produced in wafer form by shared processes, this enables a better yield of the wafers.

In a first example of a particular embodiment of the invention, the optical unit for shaping the light rays coming from the light source is made up of a transparent part surrounding at least one electroluminescent element, the surface of which is similar to a portion of an ellipsoid and forms a diopter. In this exemplary embodiment, the diopter concentrates the light rays coming from at least one electroluminescent element around a direction of maximum intensity normal to the upper face of the substrate. Rays that are parallel to the upper face of the substrate or form a small angle with this surface (for example less than 20°, preferably less than 10°, preferably less than 5°) are however not deflected much by the diopter and are therefore not concentrated by the diopter. In a motor vehicle lighting device, such rays generally do not contribute to a lighting function inasmuch as, for rays forming an angle less than 20°, they are often blocked by elements of the lighting device, such as the housing or other decorative elements. Furthermore, these rays can adversely affect the appearance of the lighting device when they are reflected unexpectedly by an element of the lighting device. In the case of a signalling lighting device provided with a lighting device outer lens separating the array arrangement from the outside of the vehicle, in which light sources are arranged at a very small distance from a lighting device outer lens or are adhesively bonded to said outer lens, even rays forming an angle less than 5° may be reflected toward the inside of the lighting device by said outer lens, this possibly adversely affecting the appearance of the lighting device. In the case of a curved outer lens, even rays having an angle less than 10° may be deflected toward the inside of the lighting device.

In a second example of a particular embodiment of the invention, the optical unit for shaping the light rays coming from the light source is made up of a reflector and a transparent part surrounding at least one electroluminescent element. The surface of a first portion of the transparent part of the optical unit for shaping the light rays is similar to a portion of an ellipsoid. In this exemplary embodiment, the diopter concentrates the light rays coming from the at least one electroluminescent element around a direction of maximum intensity normal to the upper face of the substrate. Rays that are parallel to the upper face of the substrate or form a small angle (for example less than 20°, preferably less than 10°, preferably less than 5°) are deflected by the reflectors. For example, a first portion forms a first ellipsoidal diopter and a second portion, at least partially facing the reflectors, is a plane forming a planar diopter which does not deflect the light deflected by the reflectors much. In this way, these rays do not adversely affect an appearance of the array arrangement and contribute to the performance of a function, such as a regulatory function, by the lighting device.

Advantageously, a portion of the transparent part of the optical unit for shaping the light rays is designed such that a beam of rays that are deflected by the reflectors is not deflected, or is not deflected much, by the transparent part of the optical unit for shaping the light rays. In this way, the optical unit for shaping the light rays is simplified. For example, a first portion forms a first convex diopter and a second portion, at least partially facing the reflectors, is a plane forming a planar diopter which does not deflect the light deflected by the reflectors much.

Advantageously, the electronic circuit has an integrated circuit designed to supply power to the elementary light source. In this way, it is not necessary to provide a power supply circuit for the light source on the support for light sources, and the complexity and costs for producing said support are limited.

Advantageously, the integrated circuit is designed to supply power to the at least one electroluminescent element according to a setpoint, for example a setpoint signal may be received by the connections for controlling the light source, the power supply from the integrated circuit can be received by other connections of the light source, and the integrated circuit supplies power to the at least one electroluminescent element depending on said setpoint. In this way, a support for the array arrangement of light sources can be simplified and the cost is limited.

Advantageously, the integrated circuit is a control circuit, for example an elementary circuit of an active-matrix control circuit for the array arrangement. In this way, a step of mounting such an active-matrix circuit on the support forming the array arrangement is avoided. In particular, it is often requested that the signalling devices take various forms, or the manufacture of supports comprising active-matrix control circuits for the light sources requires high investments for each model, this making it expensive to produce models with varied dimensions.

Advantageously, the at least one electroluminescent element is embedded in the substrate, such that the distance between the emitting surface of the at least one electroluminescent element and an output diopter of the optical unit for shaping the light rays coming from the at least one electroluminescent element is increased. As a result. a height of the light source is reduced, the dispersion of heat from the electroluminescent element is improved, and the production costs are decreased. In addition, moving the at least one electroluminescent element away from the output surface of the optical unit for shaping the light rays coming from said at least one electroluminescent element makes it possible to improve a light intensity in a direction of maximum intensity of the light emitted by the light source.

Advantageously, the at least one electroluminescent element is disposed such that its emitting surface is flush with the upper face of the substrate. This is advantageously obtained by a method, preferably an on-wafer method, comprising the making up of a collective substrate in a method having the following steps:
disposing electroluminescent elements on a planar surface of a temporary holding plate,
optionally disposing integrated control circuits on the temporary holding plate,
covering the planar surface and electroluminescent elements with a layer of resin of dielectric type,
making up an interconnection network in said layer of resin, notably by laser ablation of parts of the layer of resin, said network making it possible to supply power to the electroluminescent elements,
optionally adding additional layers of resin and additional interconnection networks; the network can then have one or more layers,
making up contacts on the last layer of resin.

At the end of this method, the collective substrate is made up, the whole can then be turned over and the temporary holding plate can be removed. In this way, a collective substrate is obtained.

Optical units for shaping the light rays can then be associated with electroluminescent elements. In this way, the method remains collective until the singulation of light sources according to the invention.

The optical units for shaping the light rays are associated with the electroluminescent elements in a method comprising at least one molding of an optical unit directly onto at least one electroluminescent element and at least partially onto the upper face of the substrate.

Alternatively, the optical unit for shaping the light rays is molded onto the plurality of light sources and/or the upper face of the substrate and onto a support on which are arranged the light sources and said support is not cut. In this way, it is possible to produce optical units corresponding to each electroluminescent element of the arrangement of light sources, in particular optical units having a different geometry adapted to a position of the electroluminescent element in the matrix of electroluminescent elements, in particular in the specific case of a support having a curved surface, for example so as to ensure the sources have one and the same main emission direction. This is particularly advantageous since it makes it possible to avoid the logistical difficulties, quality problems and costs that are linked with the management of multiple stocks of light sources having different optical units and with the positioning of each of these sources on the support.

Advantageously, the light source has a single electroluminescent element.

Advantageously, the light source has a plurality of electroluminescent elements.

Advantageously, each of the electroluminescent elements interacts with the optical unit for shaping the light rays. In this way, a number of light sources for making a given contribution to a signalling function is reduced, a number of operations for manufacturing light sources (in particular singulation and classification operations) and a number of components to be mounted on the support to produce the array arrangement is reduced. As a result, the cost of manufacturing and the complexity of the array arrangement are particularly reduced.

Alternatively, at least one of the electroluminescent elements does not interact with a transparent portion of the optical unit for shaping the light rays such that a footprint of the at least one electroluminescent element on the substrate is reduced. It is then possible to add electroluminescent elements while preserving a footprint of the light source, or increasing it very little, at least while preserving a footprint which is significantly less than when all the electroluminescent elements have an optical element dedicated to the at least one light source. For example, at least one electroluminescent element is placed in a central zone of the substrate and interacts with a transparent part of the optical unit for shaping the light rays, and the electroluminescent element is placed in a peripheral zone of the substrate and does not interact with the transparent part of the optical unit for shaping the light rays, that is to say that the rays emitted by the electroluminescent element that are directed toward the outside of the motor vehicle lighting device do not pass through the transparent part.

Advantageously, each electroluminescent element corresponds to an optical portion for shaping the light rays, which itself ensures an identical or at least similar light distribution to that of the other electroluminescent elements of the light source. In this way, the electroluminescent elements of the light source are perceived as homogeneous. Preferably, the spacing between the electroluminescent elements of the array arrangement is substantially identical, whether or not said electroluminescent elements belong to different light sources. In this way, the electroluminescent elements of the entire array arrangement are perceived as homogeneous.

Alternatively, all the electroluminescent elements correspond to one and the same optical unit for shaping the light rays, which ensures an identical light distribution for each electroluminescent element. As a result, each electroluminescent element corresponds to a portion of the same optical unit for shaping the light rays that is made in one piece and constitutes a single part. In this way, a single optical unit for shaping the light rays can be manufactured for multiple light sources.

Again alternatively, the optical unit for shaping the light rays is made up of an assembly of separate and similar optical elements. This makes it possible for example to group the similar electroluminescent elements such that a homogeneity of the array arrangement is maximized whereas a number of light sources that must be arranged on the support is reduced. In this way, the assembly costs are reduced and a connection network of the light sources is simplified, this making it possible to use a less expensive support.

Again alternatively, the optical unit for shaping the light rays is made up of an assembly of separate optical elements taking shapes that vary depending on the use of the light source.

Again alternatively, all the electroluminescent elements correspond to one and the same optical unit for shaping the light rays, preferably made in one piece, and an optical unit for shaping the light rays that is made in one piece ensures different light distributions for the electroluminescent elements. In this way, one and the same light source makes it possible to have a different light distribution for certain electroluminescent elements, notably when electroluminescent elements must participate in different functions.

Advantageously, the light source has multiple electroluminescent elements arranged in lattices, that is to say that they make up a subassembly of the overall array arrangement.

Advantageously, the electroluminescent elements are disposed on the light sources such that the electroluminescent elements are identically spaced apart in the array arrangement of light sources along main directions of this array arrangement. For example, when the lattice of the array arrangement is square, that is to say that the light sources are in an array arrangement having two main directions which are orthogonal and that the light sources are identically spaced apart along these two directions, the lattice of the light source is preferably square. Preferably, the light source has 4 electroluminescent elements.

In another example, when the lattice of the array arrangement is rectangular, that is to say that the light sources are disposed in a bidimensional matrix extending along two orthogonal directions but that the light sources are not necessarily identically spaced apart along these two directions, the lattice of the light source is preferably rectangular, that is to say that it has at least 4 electroluminescent elements disposed at the corners of a rectangle. Preferably, such a lattice has 4 electroluminescent elements.

In another example, when the lattice of the array arrangement is rectangular, the lattice is preferably linear, that is to say that the electroluminescent elements are aligned along a given direction. Preferably, the lattice has 2 electroluminescent elements. Preferably, the 2 electroluminescent elements are aligned horizontally. Preferably, each of these electroluminescent elements has a dedicated optical unit for shaping the light rays, which is preferably a portion of an ellipsoid, and a cross section through the output diopter of each of the optical units for shaping the light rays is a portion of an ellipse.

In another example, when the lattice of the array arrangement is a parallelogram, that is to say that the light sources are aligned along 2 non-orthogonal directions, the lattice of the light source is preferably a parallelogram, that is to say that the electroluminescent elements are disposed at the corners of a parallelogram. Preferably, the parallelogram lattice of the light source is such that its sources are disposed along the same directions as those of the lattice of the array arrangement. Preferably, such a lattice has 4 electroluminescent elements.

In another example, when the lattice of the array arrangement is hexagonal, the lattice may be triangular or hexagonal. Preferably, such a light source has 3 individual light sources.

When the light source has multiple electroluminescent elements, it is particularly advantageous for the electronic circuit of the light source to have an integrated circuit able to supply power individually, that is to say independently or simultaneously, to each of the electroluminescent elements according to one or more setpoints received by the light source. In this way, a number of connection contacts necessary to supply power to the light source to control the electroluminescent elements is reduced, a support for the array arrangement of light sources is simplified, and a cost of a motor vehicle signalling module having the array arrangement of light sources is reduced.

When the light source has multiple electroluminescent elements, it is particularly advantageous for the electronic circuit of the light source to have an integrated circuit able to supply power individually, that is to say independently or simultaneously, to each of the electroluminescent elements according to one or more setpoints received by the light source. In this way, a number of connection contacts necessary to supply power to the light source to control the electroluminescent elements is reduced, a support for the array arrangement of light sources is simplified, and a cost of a motor vehicle signalling module having the array arrangement of light sources is reduced. In addition, a cost of integrating said integrated circuit is decreased when said integrated circuit makes it possible to supply power to multiple electroluminescent elements.

Advantageously, such an integrated circuit is an element of a control system of the active matrix type, such that an electrical signal received for a given electroluminescent element of the light source makes it possible to supply electrical power to said electroluminescent element even when no electrical signal is received to supply electrical power to said electroluminescent element. Such a circuit makes it possible to obtain a maximum luminous flux of the light source even when no electrical signal for the supply of power to the electroluminescent elements is received. For example, a light source having 4 electroluminescent elements and an integrated circuit able to supply power to them individually has a total number of connection contacts fewer than or equal to 7, preferably equal to 6. In this way, a support for an array arrangement of light sources for individually activating all the electroluminescent elements of the light sources that are arranged there is particularly simplified and its cost is reduced.

Advantageously, such an integrated circuit is able to sequentially receive, at one and the same input, electrical signals relating to multiple electroluminescent elements of one and the same light source and to supply power to said electroluminescent elements depending on the information sequentially received. This makes it possible to reduce the number of electrical contacts on the lower face of the substrate even further. For example, a light source having 4 electroluminescent elements and an integrated circuit able to supply power to them individually has a total number of connection contacts fewer than or equal to 4, preferably equal to 3. In this way, a support for an array arrangement of light sources for individually activating all the electroluminescent elements of the light sources that are arranged there is particularly simplified and its cost is reduced.

When the electronic circuit comprises an integrated circuit, an active-matrix display system can be produced without the support needing circuits having thin-film transistors, known to a person skilled in the art under the acronym TFT, the manufacture of which requires the development of masks, this development having a high cost, which must be repeated for each new shape of the support for an array arrangement. In this way, the signalling devices comprising light sources according to the invention can be easily adapted to constraints on the shapes of signalling devices which vary significantly from one vehicle to the next, without generating such development costs.

Advantageously, the optical unit for shaping the light rays has a colored filter, such that the light rays coming from the electroluminescent elements are filtered. Preferably, the filter only lets through rays with a wavelength close to that of the rays coming from the at least one electroluminescent element. Preferably, in the case of a rear position light, the filter only lets through red light. In this way, an appearance of the light source when it is turned off is improved.

Advantageously, the upper face of the substrate has a coating which absorbs the light rays so as to avoid light interference. For example, the upper face has a matte black coating.

Advantageously, a protective mineral coating is applied to all the non-conductive faces of the light source, so as to improve resistance to corrosion, notably in the surroundings of a motor vehicle.

The present invention will now be described by way of examples that are merely illustrative and that in no way limit the scope of the invention, and with reference to the accompanying illustrations, in which:

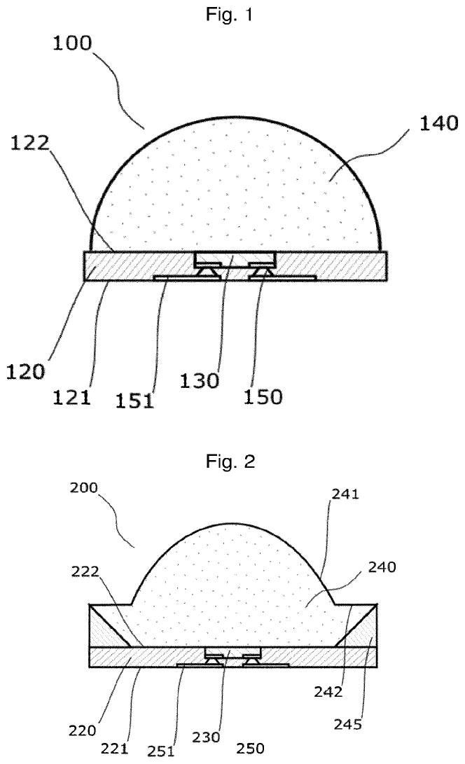

FIG. 1 schematically and partially depicts a sectional view through a light source according to a first embodiment of the invention;

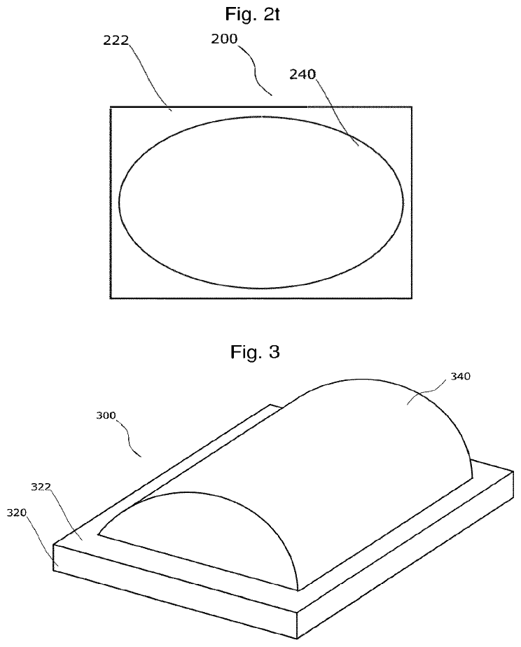

FIG. 2 schematically and partially depicts a sectional view through a light source according to a second embodiment of the invention;

FIG. 2t schematically and partially depicts a view, from a point located on an axis normal to the upper face of the substrate, that makes it possible to observe said upper face of the substrate, of a light source according to a second embodiment of the invention;

FIG. 3 schematically and partially depicts a perspective view of a light source according to a third embodiment of the invention;

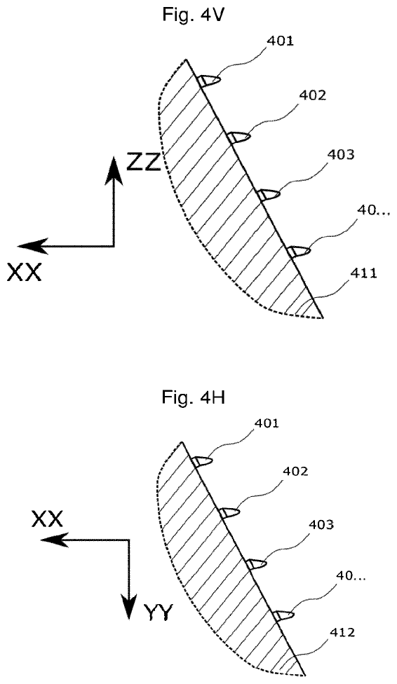

FIG. 4V schematically and partially depicts a sectional view through a support for an array arrangement of light sources according to the invention;

FIG. 4H schematically and partially depicts a sectional view through a support for an array arrangement of light sources according to the invention.

FIG. 1 depicts a sectional view through a light source 100 according to a first embodiment of the invention, along a plane orthogonal to the substrate 120.

The light source of [FIG. 1] forms part of an array arrangement of identical light sources of a motor vehicle lighting module.

The light source has a substrate 120 provided with an upper face 122, a lower face 121 opposite to the upper face, and an electronic circuit 151.

Here, the substrate 120 defines the footprint of the light source 100. In this case, the substrate 120 and therefore the light source 100 have a square footprint with a side length of 200 μm. The optical unit 140 for shaping the light rays is spherical and has a radius of 80 μm.

The light source has an electroluminescent element 130 of the micro-LED type which is mounted on the upper face 122 of the substrate 120 and has a light-emitting part, said emitting part having a surface area of 900 μm² as viewed from an axis normal to the outer face of the substrate.

The light source in addition has an optical unit for shaping the light rays. In the embodiment of [FIG. 1], the optical unit for shaping the light rays forms, above the upper face of the substrate, a spherical diopter designed to concentrate the light rays coming from the at least one electroluminescent element around an optical axis normal to the substrate. The emitting surface of the at least one electroluminescent element is close to said optical axis.

In addition, the lower face has connection contacts 151 connected to the electronic circuit 150, said contacts being in this case made in the form of pads, that is to say contact pads, the electronic circuit 151 being designed to supply power to the electroluminescent element 130 when the connection contacts are connected to an electrical power supply.

FIG. 2 depicts a view of a light source 200 according to a second embodiment of the invention.

The light source of [FIG. 2] forms part of an array arrangement of identical light sources of a motor vehicle lighting module.

The light source has a substrate 220 provided with an upper face 222, a lower face 221 opposite to the upper face, and an electronic circuit 250. The substrate 220 has a rectangular footprint, with a large side and a small side.

The light source 200 has an electroluminescent element 230 of the micro-LED type which is mounted on the upper face 222 of the substrate 220 and has a light-emitting part, said emitting part having a surface area of 900 μm² as viewed from an axis normal to the outer face of the substrate 220.

The light source 200 in addition has an optical unit 240 for shaping the light rays. In the embodiment of [FIG. 2], the optical unit 240 for shaping the light rays forms, above the upper face of the substrate, a diopter 241 of which the surface is a portion of an ellipsoid and which is designed to concentrate the light rays coming from the electroluminescent element 230 around a direction of maximum intensity that is normal to the substrate 220. The emitting surface of the at least one electroluminescent element is close to said normal direction of maximum intensity.

In addition, the optical unit 240 for shaping the light rays has reflectors 245 designed to concentrate the light rays coming from the electroluminescent element 230. In the embodiment of [FIG. 2t], the reflectors 245 are prisms with a triangular cross section that were formed by a process for successively depositing material. The material used is an alloy of copper selected for its high reflectivity characteristics. In this particular embodiment, those portions 242 of the optical unit for shaping the light rays that are located in line with the reflectors are planar and prisms are disposed at the edges of the rectangular substrate 220. These reflectors make it possible to concentrate, around a direction of maximum intensity that is normal to the substrate, light rays that are parallel to or form a small angle with a plane of the upper face 222 of the substrate 220.

When the light source 200 is mounted on a support forming a lighting module of a motor vehicle signalling device, it is mounted such that the direction off maximum intensity of the light source 200 is disposed substantially along a front-rear axis of the motor vehicle. The light source 200 is in addition oriented such that the long side of the substrate is substantially horizontal. As a result, the light rays coming from the at least one electroluminescent element 230 are concentrated more around a horizontal plane than around a vertical plane. Such a distribution of the light rays is particularly favorable to the performance of a signalling function, such as a rear position light function, position light function or brake light function.

FIG. 2t depicts a view of the light source 200 according to the embodiment in [FIG. 2], seen from above, that is to say from a viewpoint orthogonal to the upper face 222 of the substrate 220.

FIG. 3 depicts a perspective view of a light source 300 according to a third embodiment of the invention.

The light source of [FIG. 3] forms part of an array arrangement of identical light sources of a motor vehicle lighting module.

The light source 300 has a substrate 320 provided with an upper face, a lower face opposite to the upper face, and an electronic circuit, which is not depicted. The substrate 320 has a rectangular footprint, with a large side and a small side. The lower face has connection contacts, not depicted, which are connected to the electronic circuit, which is not depicted.

The light source has an electroluminescent element and an optical unit 340 for shaping the light rays. In the embodiment of [FIG. 2t], the optical unit 340 for shaping the light rays forms, above the upper face of the substrate 322, a diopter of which the surface is a portion of an cylinder with a circular base and which is designed to concentrate the light rays coming from the electroluminescent element around a plane normal to the substrate. The emitting surface of at least one electroluminescent element is close to said normal direction of maximum intensity.

FIG. 4V depicts a partial view of an array arrangement of light sources from a sectional viewpoint in a plane XXZZ through a support for light sources of a lighting module.

The light sources 401, 402, 403, 40 . . . etc. each have a substrate provided with an upper face, a lower face opposite to the upper face, an electronic circuit and electrical contacts located on the lower face of the substrate. The substrate has a rectangular footprint, with a large side and a small side.

The light sources have an electroluminescent element and an optical unit for shaping the light rays. In the embodiment of [FIG. 4V], the optical unit for shaping the light rays from each of the light sources 401, 402, 403, 40 . . . etc. is asymmetrical, such that it is able to concentrate the light rays about a direction of maximum intensity parallel to a front-rear axis XX of the motor vehicle, although the support 411 for the array arrangement of light sources is inclined in a plane XXZZ comprising the front-rear axis XX and a vertical axis ZZ.

FIG. 4H depicts a view of an array arrangement of light sources from a sectional viewpoint in a plane XXYY of a support for light sources of a lighting module, which are similar in all respects to those of [FIG. 4V] except in that the optical unit for shaping the light rays is asymmetrical, such that it is able to concentrate the light rays about a direction of maximum intensity that is parallel to a front-rear axis XX of the motor vehicle, although the support 412 for the array arrangement of light sources is inclined in a plane XXZZ comprising the front-rear axis XX and a vertical axis ZZ.

The invention is not limited to the embodiments specifically given in this document by way of non-limiting examples, and extends in particular to all equivalent means and to any technically operational combination of these means. As a result, the features, variants and various embodiments of the invention may be combined with one another, in various combinations, as long as they are not mutually incompatible or mutually exclusive.

1. A light source for an array arrangement of light sources for a motor vehicle signalling lighting module, the light source having:
a substrate having an upper face, a lower face opposite to the upper face, and an electronic circuit,
at least one electroluminescent element which is mounted on the upper face of the substrate and has a light-emitting part,
an optical unit for shaping the rays emitted by said electroluminescent element,
said lower face having connection contacts connected to the electronic circuit, the electronic circuit being designed to supply power to the at least one electroluminescent element,
the light-emitting part of the at least one electroluminescent element having a surface area less than 40 000 μm²,
said optical unit comprising an optical element made by molding onto at least one electroluminescent element and at least partially onto the upper face of the substrate.

2. The light source as claimed in claim 1, wherein the surface area of the emitting part of the at least one electroluminescent element is at least two times smaller than the surface area of the upper face of the substrate and/or the surface area of the emitting part of the at least one electroluminescent element is at least two times smaller than the surface area of the useful output surface of the optical unit for shaping the light rays coming from the at least one electroluminescent element.

3. The light source as claimed in claim 1, wherein the optical unit for shaping the rays emitted by the at least one electroluminescent element has a convergent optical unit having an oval or elliptical cross section in a plane parallel to the upper face of the substrate.

4. The light source as claimed in claim 1, wherein the optical unit for shaping the rays emitted by the at least one electroluminescent element concentrates said rays more around a horizontal plane of the vehicle than around a vertical plane of the vehicle.

5. The light source as claimed in claim 1, wherein the optical unit for shaping the light rays is rotationally asymmetrical in relation to any axis normal to the upper face of the substrate and/or asymmetrical in relation to any vertical plane of the vehicle and/or asymmetrical in relation to any horizontal plane of the vehicle.

6. The light source as claimed in claim 1, wherein the optical unit for shaping the rays emitted by the at least one electroluminescent element has reflectors.

7. The light source as claimed in claim 6, wherein, the reflectors are made by successive depositions of a reflective material on the substrate itself.

8. The light source as claimed in claim 1, wherein an antireflection coating and/or a mineral coating is applied to the shaping optical unit and/or to the sides of the light source.

9. The light source as claimed in claim 1, wherein the light source has a footprint and/or connection contacts which is/are asymmetrical along at least a plane normal to a plane of the substrate that passes through its center.

10. The light source as claimed in claim 1, wherein the electronic circuit of the substrate has an integrated circuit designed to supply power to at least one electroluminescent element.

11. A signalling device contributing to and/or performing a regulatory rear position light function and/or brake light function and/or turn indicator function, wherein it has a support for an array arrangement of light sources as claimed in claim 1, forming a lighting module.

12. A method for manufacturing a light source as claimed in claim 1, wherein the method comprises:
a step of making up a common substrate from electroluminescent elements comprising a plurality of electroluminescent elements, having an upper face on which are mounted the electroluminescent elements and a lower face having connection contacts and electronic circuits for connecting the electroluminescent elements, such that the electroluminescent elements can be supplied with power via the lower face of the common substrate,
a step of making optical units for shaping the light rays coming from the electroluminescent elements by molding directly onto at least one electroluminescent element and at least partially onto the upper face of the substrate,
a step of singulating the common substrate, yielding a plurality of light sources.

13. The light source as claimed in claim 2, wherein the optical unit for shaping the rays emitted by the at least one electroluminescent element has a convergent optical unit having an oval or elliptical cross section in a plane parallel to the upper face of the substrate.

14. The light source as claimed in claim 2, wherein the optical unit for shaping the rays emitted by the at least one electroluminescent element concentrates said rays more around a horizontal plane of the vehicle than around a vertical plane of the vehicle.

15. The light source as claimed in claim 2, wherein the optical unit for shaping the light rays is rotationally asymmetrical in relation to any axis normal to the upper face of the substrate and/or asymmetrical in relation to any vertical plane of the vehicle and/or asymmetrical in relation to any horizontal plane of the vehicle.

16. The light source as claimed in claim 2, wherein the optical unit for shaping the rays emitted by the at least one electroluminescent element has reflectors.

17. The light source as claimed in claim 2, wherein an antireflection coating and/or a mineral coating is applied to the shaping optical unit and/or to the sides of the light source.

18. The light source as claimed in claim 2, wherein the light source has a footprint and/or connection contacts which is/are asymmetrical along at least a plane normal to a plane of the substrate that passes through its center.

19. The light source as claimed in claim 2, wherein the electronic circuit of the substrate has an integrated circuit designed to supply power to at least one electroluminescent element.

20. A signalling device contributing to and/or performing a regulatory rear position light function and/or brake light function and/or turn indicator function, wherein it has a support for an array arrangement of light sources as claimed in claim 2, forming a lighting module.
